(19) United States
(12) Patent Application Publication
(10) Pub. No.: US 2013/0037953 A1
(43) Pub. Date: Feb. 14, 2013

(54) THROUGH SILICON VIA STRUCTURE AND MANUFACTURING METHOD THEREOF

(71) Applicants: Hsin-Yu Chen, Nantou County (TW); Ching-Li Yang, Ping-Tung Hsien (TW)

(72) Inventors: Hsin-Yu Chen, Nantou County (TW); Ching-Li Yang, Ping-Tung Hsien (TW)

(21) Appl. No.: 13/207,406

(22) Filed: Aug. 10, 2011

(51) Int. Cl. H01L 23/48; H01L 21/768

(52) U.S. Cl. 257/751; 438/653; 257/E23.011; 257/E21.597

(57) ABSTRACT

A manufacturing method for a through silicon via structure includes the following steps. First, a substrate is provided, and a through silicon hole is formed in the substrate. An outer plasma enhanced oxide layer is formed on the surface of the through silicon hole, and then a liner layer is formed on the surface of the outer plasma enhanced oxide layer. An inner plasma enhanced oxide layer is formed on the surface of the liner layer. Finally, a conductor is formed on the surface of the inner plasma enhanced oxide layer to completely fill the through silicon hole.

### BACKGROUND OF THE INVENTION

1. Field of the Invention

The present invention relates to a through silicon via structure and a manufacturing method thereof, and more particularly, to a through silicon via structure and a manufacturing method thereof that can effectively block metal atoms from diffusing out of the through silicon via structure.

2. Description of the Prior Art

A response speed of IC circuits is related to the longest linking distance between devices disposed on a chip. Since a vertical distance between adjacent layers is much shorter than the width of a single-layer chip, IC circuits with a three-dimensional structure can shorten the linking distance of devices disposed on a chip. Accordingly, their operational speed can be increased when a chip is designed with a vertical packed structure. To form this packed structure, two or more semiconductor dies with IC circuits are connected. The conductors are required to be formed in vertical layer structures to electrically connect to different semiconductor devices, thereby integrating them into packed semiconductor dies. Through silicon vias (TSVs) are designed to break the limit of the chip connection process, especially for a chip connection process with a higher performance requirement and higher density. The interconnection between chips carried out by TSVs means signal transmission can be more efficient.

Currently, copper has replaced aluminum as the conductive material of through silicon via structures due to its low resistance. Copper has a high diffusion coefficient, however, and diffuses into semiconductor substrates immediately after being exposed to silicon or silicon oxide, which may damage the semiconductor devices.

### SUMMARY OF THE INVENTION

It is therefore one of the objectives of the present invention to provide a through silicon via structure and a manufacturing method thereof to block metal atoms from diffusing out of the through silicon via structure.

The present invention provides a through silicon via structure located in a substrate. The through silicon via structure includes a conductor, an inner plasma enhanced oxide layer, a liner layer, and an outer plasma enhanced oxide layer. The inner plasma enhanced oxide layer surrounds the conductor. The liner layer surrounds the inner plasma enhanced oxide layer. The outer plasma enhanced oxide layer surrounds the liner layer. The substrate surrounds the outer plasma enhanced oxide layer, and the substrate is directly in contact with the outer plasma enhanced oxide layer.

The present invention provides a manufacturing method of a through silicon via structure, illustrated by the following steps. First, a substrate is provided, and a through silicon hole is formed in the substrate. Next, an outer plasma enhanced oxide layer is formed on the through silicon hole, and a liner layer is formed on the outer plasma enhanced oxide layer. An inner plasma enhanced oxide layer is formed on the liner layer. Finally, a conductor is formed on the inner plasma enhanced oxide layer to completely fill the through silicon hole.

In accordance with the through silicon via structure and the manufacturing method thereof in the present invention, the conductor is surrounded by the inner plasma enhanced oxide layer, the liner layer, and outer plasma enhanced oxide layer in sequence, such that metal atoms can be blocked from diffusing out of the through silicon via structure, thereby preventing the semiconductor devices from damage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a through silicon via structure according to a first embodiment of the present invention.

FIG. 2 is a schematic diagram illustrating a through silicon via structure according to a second embodiment of the present invention.

FIG. 3 through FIG. 10 are schematic diagrams illustrating a manufacturing method of the through silicon via structure according to the second embodiment of the present invention.

### DETAILED DESCRIPTION

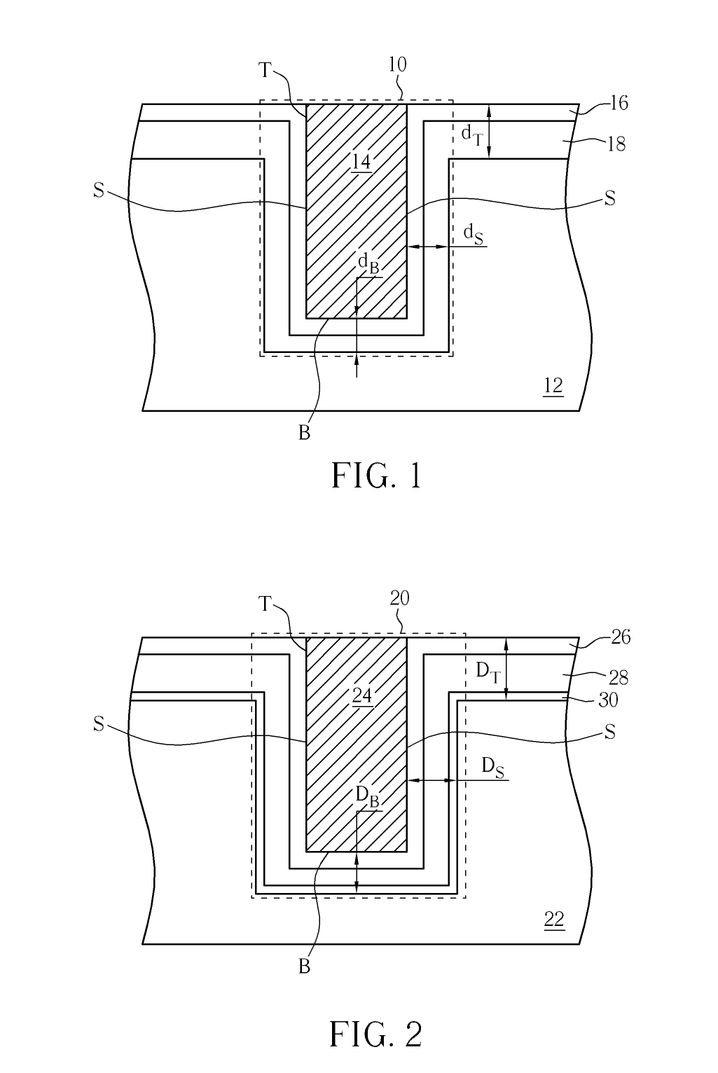

Please refer to FIG. 1, which illustrates a through silicon via structure according to a first embodiment of the present invention. As shown in FIG. 1, a through silicon via structure 10 is located in a substrate 12, and the through silicon via structure 10 includes a conductor 14, a plasma enhanced oxide layer 16 and a liner layer 18. The plasma enhanced oxide layer 16 surrounds the conductor 14, and the liner layer 18 surrounds the plasma enhanced oxide layer 16. In the present embodiment, a sidewall S and a bottom B of the conductor 14 are surrounded by a double-layer structure of the plasma enhanced oxide layer 16/liner layer 18, such that metal atoms can be blocked from diffusing out of the conductor 14, thereby preventing the degeneration of a semiconductor device's performance. In the present embodiment, the conductor 14 can be metal such as copper, and the conductor 24 further includes a barrier layer (not shown) and a seed layer (not shown). The liner layer 18 can be silicon oxide deposited on substrate 12 by CVD process (such as LPCVD). It should be noted that the double-layer structure of the plasma enhanced oxide layer 16/liner layer 18 has different deposition thicknesses near the bottom B, sidewall S, and a top T of the conductor 14, respectively. The deposition thicknesses near the bottom B, sidewall S, and the top T of the conductor 14 are respectively denoted as d_{B}, d_{S}, and d_{T}. In the present embodiment, the averaged values of d_{B}, d_{S}, and d_{T} are shown in Table 1. The value of the deposition thickness d_{T} is almost twice that of the deposition thickness d_{B} and d_{S}. In the present embodiment, the deposition thickness d_{B} and the deposition thickness d_{T} can be increased to enhance the performance of blocking metal atoms from diffusion; consequently, the deposition thickness d_{T} tends to be increased by a large amount.

TABLE 1

| Deposition | deposition | deposition |
|---|---|---|
| thickness (d_{B}) | thickness (d_{S}) | thickness (d_{T}) |
| 1840 (angstrom) | 1890 (angstrom) | 3500 (angstrom) |

Please refer to FIG. 2, which illustrates a through silicon via structure according to a second embodiment of the present invention. As shown in FIG. 2, a through silicon via structure 20 is located in a substrate 22, and the through silicon via structure 20 includes a conductor 24, an inner plasma enhanced oxide layer 26, a liner layer 28, and an outer plasma enhanced oxide layer 30. The inner plasma enhanced oxide layer 26 surrounds the conductor 24. The liner layer 28 surrounds the inner plasma enhanced oxide layer 26. The outer plasma enhanced oxide layer 30 surrounds the liner layer 28. The substrate 22 surrounds the outer plasma enhanced oxide layer 30, and is directly in contact with the outer plasma enhanced oxide layer 30. Similarly, in the present embodiment, the conductor 24 can be metal such as copper, and the conductor 24 further includes a barrier layer (not shown) and a seed layer (not shown). The liner layer 28 can be silicon oxide deposited on outer plasma enhanced oxide layer 30 by CVD process (such as LPCVD). As compared with the aforementioned embodiment, in the present embodiment, the outer plasma enhanced oxide layer 30 are additionally interposed between the substrate 22 and the liner layer 28; thus, the conductor 24 is surrounded by a tri-layer structure of the inner plasma enhanced oxide layer 26/liner layer 28/outer plasma enhanced oxide layer 30. In the present embodiment, the deposition thicknesses of the tri-layer structure of the inner plasma enhanced oxide layer 26/liner layer 28/outer plasma enhanced oxide layer 30 near the bottom B, sidewall S, and the top T of the conductor 24 are respectively denoted as D_{B}, D_{S}, and D_{T}. In the present embodiment, the averaged values of D_{B}, D_{S}, and D_{T} are shown in Table 2.

TABLE 2

| deposition | deposition | deposition |
|---|---|---|
| thickness (D_{B}) | thickness (D_{S}) | thickness (D_{T}) |
| 2020 (angstrom) | 2150 (angstrom) | 3350 (angstrom) |

Comparing Table 2 with Table 1, the deposition thicknesses D_{B} and D_{S} of the tri-layer structure of the inner plasma enhanced oxide layer 26/liner layer 28/outer plasma enhanced oxide layer 30 are respectively thicker than the deposition thicknesses d_{B} and d_{S} of the double-layer structure plasma enhanced oxide layer 16/liner layer 18, but the deposition thickness D_{T} in the present embodiment is thinner than the deposition thickness d_{T} in the aforementioned embodiment. On condition that the deposition thickness D_{T} near the top T of the conductor 24 is the same as the deposition thickness d_{T} near the top T of the conductor 14, the tri-layer structure of the inner plasma enhanced oxide layer 26/liner layer 28/outer plasma enhanced oxide layer 30 in the present embodiment has thicker deposition thicknesses near the bottom B and the sidewall S of the conductor 24. As a result, in the present embodiment, metal atoms can be effectively blocked from diffusing into the substrate 22 from the bottom B and the sidewall S of the conductor 24.

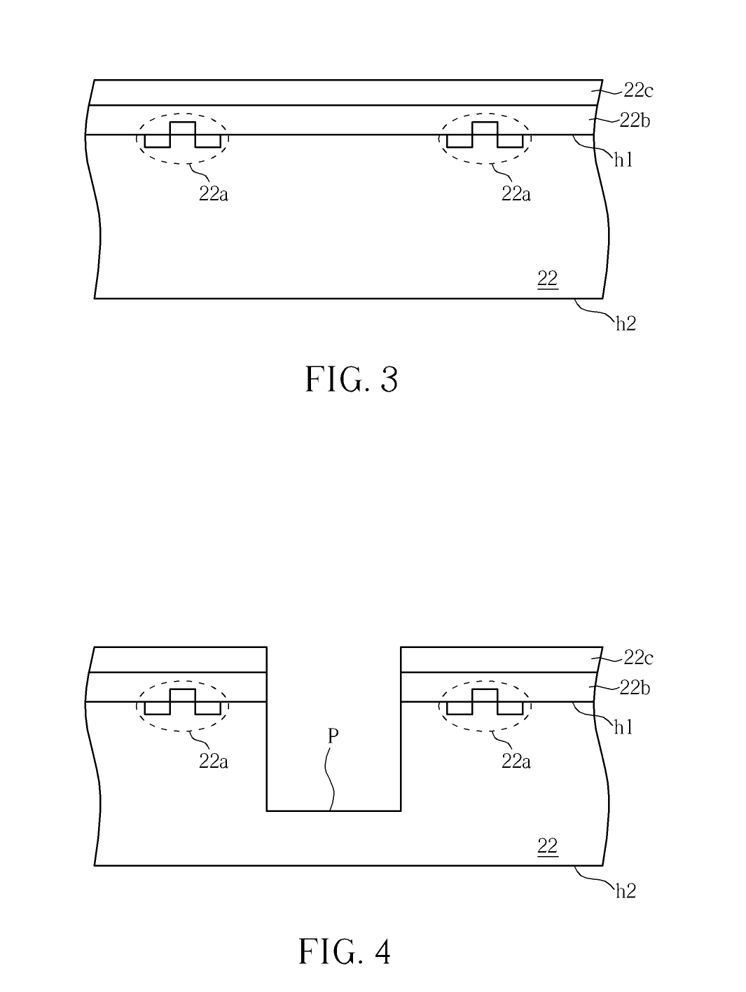

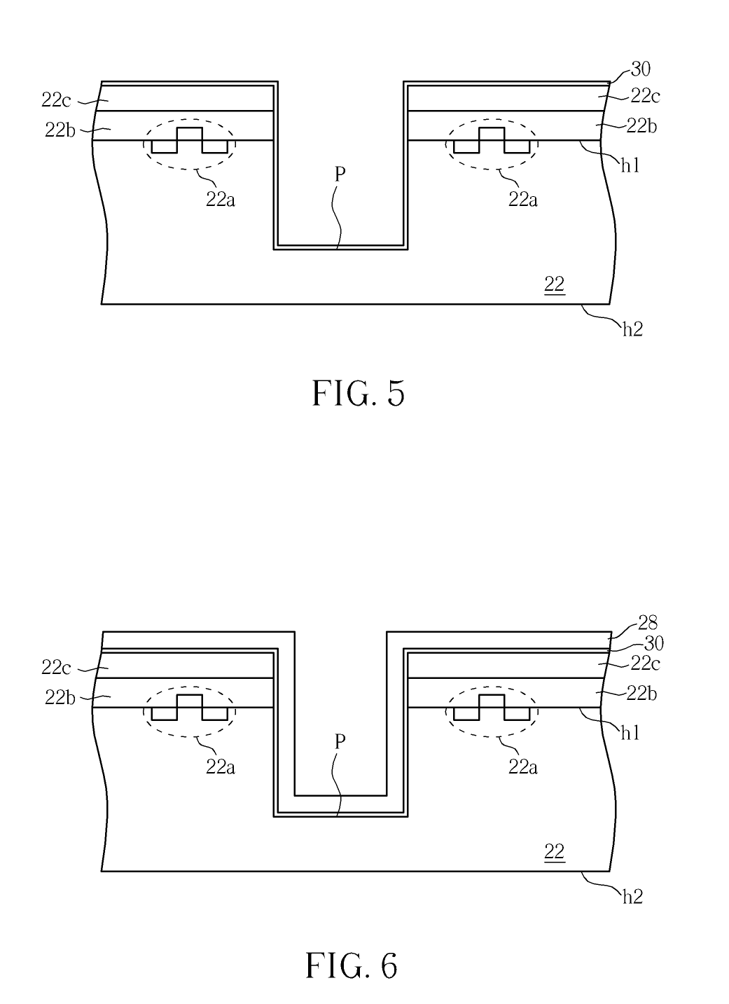

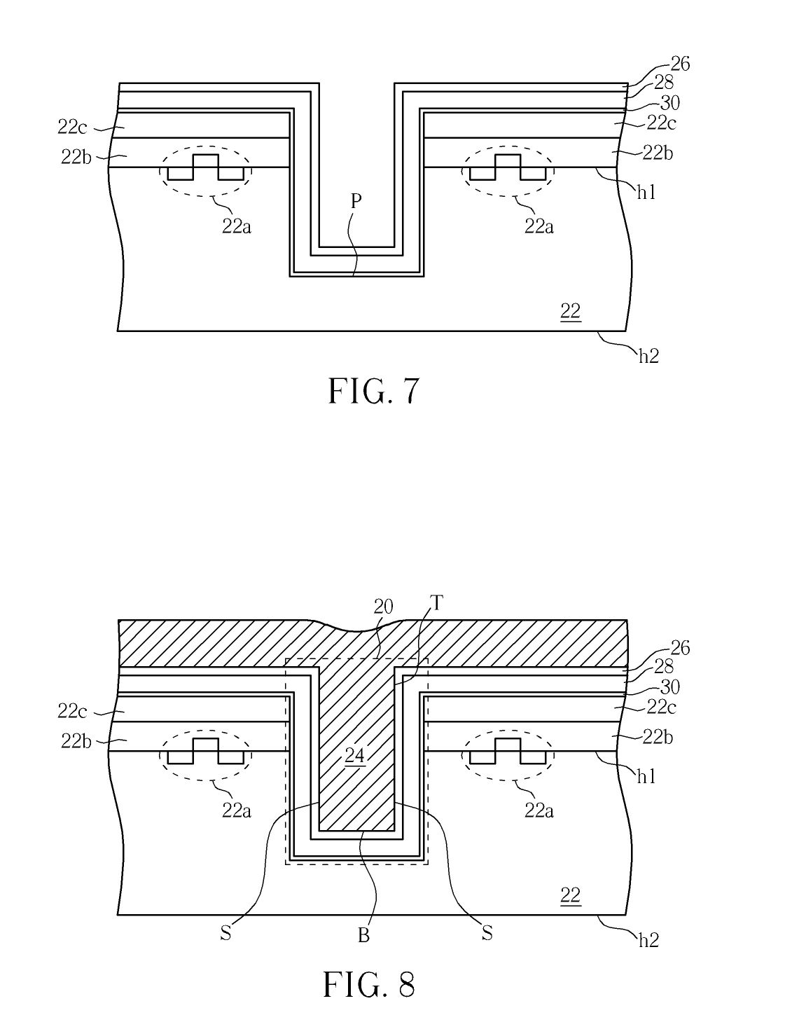

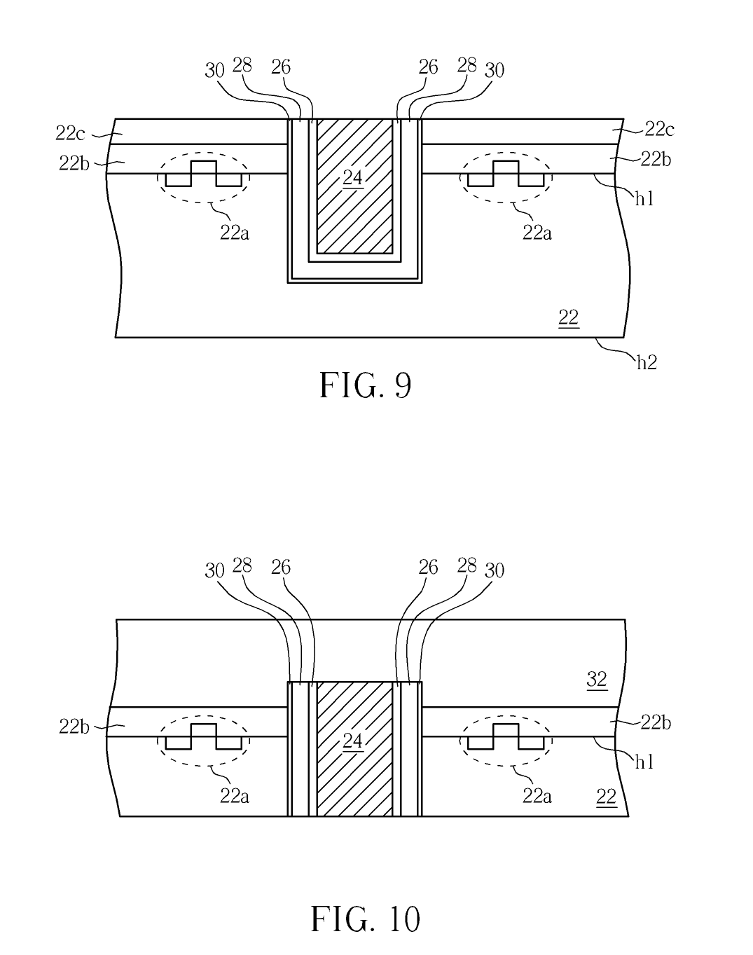

Please refer to FIG. 3 through FIG. 10, which illustrate a manufacturing method of the through silicon via structure 20 according to the second embodiment of the present invention. As shown in FIG. 3, a substrate 22 is provided, and the substrate 22 includes a plurality of devices 22a disposed on an upper surface hl of the substrate 22. In addition, a dielectric layer 22b is formed on the upper surface h1 of the substrate 22 and covers the devices 22a, and a mask layer 22c, including silicon nitride, covers the dielectric layer 22b. A patterned photoresist layer (not shown) is formed on the mask layer 22c to serve as the mask for a single-step etching process or a multi-step etching process, and then the patterned photoresist layer is removed. As shown in FIG. 4, a through silicon hole P is formed in the substrate 22 and penetrates the mask layer 22c and the dielectric layer 22b. Next, as shown in FIG. 5, an outer plasma enhanced oxide layer 30 is formed on the through silicon hole P. As shown in FIG. 6, a liner layer 28 is formed on the outer plasma enhanced oxide layer 30. As shown in FIG. 7, an inner plasma enhanced oxide layer 26 is formed on the liner layer 28. As shown in FIG. 8, a conductor 24 is formed on the inner plasma enhanced oxide layer, and the through silicon hole is fully filled with the conductor 24 by a copper electroplating process. Before the copper electroplating process, a barrier layer (not shown), including titanium, titanium nitride, tantalum, or tantalum nitride, and a seed layer is sequentially formed on the inner plasma enhanced oxide layer 26. As shown in FIG. 8, the through silicon via structure 20 according to the present embodiment is roughly formed. In the present embodiment, as shown in FIG. 9, the manufacturing method of the through silicon via structure 20 further includes a planarization process performed to remove a part of the conductor 24, the seed layer (not shown), the barrier (not shown), the inner plasma enhanced oxide layer 26, the liner layer 28, and the outer plasma enhanced oxide layer 30, such that the mask layer 22c is exposed. As shown in FIG. 10, the mask layer 22c is removed, and then an inter-metal dielectric layer 32 is formed on the through silicon via structure 20 and the dielectric layer 22. Finally, a chemical mechanical polishing process is performed on a lower surface h2 of the substrate 22 to thin down the substrate 22, so that the conductor 24 completely penetrates the substrate 22.

It should be noted that, even when a cleaning process is performed after the through silicon hole P is formed in the substrate 22, many micro particles may remain on a surface of the through silicon hole P; thus, the surface of the through silicon hole P is quite rough. In the first embodiment of the present invention, since the surface of the through silicon hole P is directly surrounded by the liner layer 18, the surface roughness of the through silicon hole P will lead to decreased deposition thicknesses d_{B} and d_{S} and increased d_{T}. In other words, a deposition thickness D_{T} near the top T of the conductor 14 must be increased correspondingly in order to obtain enough d_{B} and d_{S} for effectively blocking metal atoms from diffusing into the substrate 12 from the bottom B and the sidewall S of the conductor 14. The thicker deposition thickness d_{T} is not favorable for the planarization process as it may retard the productivity.

To solve the aforementioned problem, in the second embodiment of the present invention, the through silicon hole P is covered by the outer plasma enhanced oxide layer 30. The outer plasma enhanced oxide layer 30 is not sensitive to surface roughness, which also means the performance of plasma enhanced chemical vapor deposition process is only slightly affected by the roughness of the surface of the through silicon hole P, and therefore the outer plasma enhanced oxide layer 30 is still deposited with a low roughness. Moreover, in the second embodiment, the deposition thickness at the bottom and the sidewall of the through silicon hole P can be increased while the deposition thickness D_{T} near the top T of the conductor 24 is decreased. Accordingly, the tri-layer structure of the inner plasma enhanced oxide layer 26/liner layer 28/outer plasma enhanced oxide layer 30 not only can effectively block metal atoms from diffusing into the substrate 22, but can also improve the performance of the planarization process and enhance the productivity due to its thinner deposition thickness D_{T}.

To sum up, according to the first embodiment of the present invention, the double-layer structure of the plasma enhanced oxide layer 16/liner layer 18 of the through silicon via structure can prevent metal atoms from seriously diffusing into the substrate. According to another embodiment of the present invention, the tri-layer structure of the inner plasma enhanced oxide layer 26/liner layer 28/outer plasma enhanced oxide layer 30 of the through silicon via structure can further enhance the performance of blocking metal atoms from diffusion, and the tri-layer structure is beneficial to the subsequent planarization process.

Those skilled in the art will readily observe that numerous modifications and alterations of the device and method may be made while retaining the teachings of the invention.

What is claimed is:

1. A through silicon via structure located in a substrate, comprising:
a conductor;
an inner plasma enhanced oxide layer, surrounding the conductor;
a liner layer, surrounding the inner plasma enhanced oxide layer; and
an outer plasma enhanced oxide layer, surrounding the liner layer, wherein the substrate surrounds the outer plasma enhanced oxide layer, and is in direct contact with the outer plasma enhanced oxide layer.

2. The through silicon via structure according to claim 1, wherein the conductor comprises copper.

3. The through silicon via structure according to claim 2, wherein the conductor further comprises a barrier layer and a seed layer.

4. The through silicon via structure according to claim 1, wherein the liner layer comprises copper.

5. A manufacturing method of through silicon via structure, comprising:
providing a substrate;
forming a through silicon hole in the substrate;
forming an outer plasma enhanced oxide layer on the through silicon hole;
forming a liner layer on the outer plasma enhanced oxide layer;
forming an inner plasma enhanced oxide layer on the liner layer; and
forming a conductor on the inner plasma enhanced oxide layer, such that the conductor completely fills the through silicon hole.

6. The manufacturing method of through silicon via structure according to claim 5, wherein the substrate comprises:
a plurality of devices, disposed on an upper surface of the substrate;
a dielectric layer, formed on the upper surface of the substrate and covering the devices; and
a mask layer, covering the dielectric layer.

7. The manufacturing method of through silicon via structure according to claim 6, wherein the through silicon hole penetrates the mask layer and the dielectric layer.

8. The manufacturing method of through silicon via structure according to claim 5, wherein the conductor comprises copper.

9. The manufacturing method of through silicon via structure according to claim 8, wherein the conductor further comprises a barrier layer and a seed layer.

10. The manufacturing method of through silicon via structure according to claim 5, wherein the liner layer comprises copper.

11. The manufacturing method of through silicon via structure according to claim 5, further comprising:
performing a planarization process to remove a part of the conductor, the inner plasma enhanced oxide layer, the liner layer, the outer plasma enhanced oxide layer, such that the mask layer is exposed.

12. The manufacturing method of through silicon via structure according to claim 5, further comprising a step of performing a thinning process on a lower surface of the substrate.
